(19) United States
(12) Patent Application Publication
(10) Pub. No.: US 2014/0246325 A1
(43) Pub. Date: Sep. 4, 2014

(54) FILM-FORMING APPARATUS AND FILM-FORMING METHOD

(71) Applicants: Takayuki Tsuchiya, Hyogo (JP); Masao Marunaka, Hyogo (JP); Yasuhiro Koizumi, Hyogo (JP); Kazuo Kondo, Osaka (JP)

(72) Inventors: Takayuki Tsuchiya, Hyogo (JP); Masao Marunaka, Hyogo (JP); Yasuhiro Koizumi, Hyogo (JP); Kazuo Kondo, Osaka (JP)

(73) Assignee: SHINMAYWA INDUSTRIES, LTD., Takarasuka-shi, Hyogo (JP)

(21) Appl. No.: 14/234,589

(22) PCT Filed: May 22, 2012
(86) PCT No.: PCT/JP2012/003337

§ 371 Date: May 19, 2014

(30) Foreign Application Priority Data
Jul. 29, 2011 (JP) 2011-167061

(51) Int. Cl. C23C 28/02; C23C 14/34; C23C 14/14

(52) U.S. Cl. CPC C23C 28/02; C23C 14/14; C23C 14/34
USPC 205/122; 204/298.02; 204/192.15

(57) ABSTRACT

A film-forming apparatus (100) includes: a vacuum chamber (30) configured to store a substrate (34B) in which a through-hole is formed and a source of copper emission (35B); a vacuum pump (36) configured to decompress an interior of the vacuum chamber (30) to a predetermined degree of vacuum; a power supply (80) configured to generate electric power applied to the substrate (34B); and a driving mechanism for use in setting a distance between the substrate (34B) and the source of copper emission (35B). When a copper material emitted from the source of copper emission (35B) is deposited on one main surface of the substrate (34B) to block an opening of the through-hole in the one main surface by means of a deposited film formed of the copper material, a blocked state of the opening blocked by the deposited film is adjusted based on the distance and the electric power.

### TECHNICAL FIELD

The present invention relates to film-forming apparatuses and film-forming methods.

### BACKGROUND ART

As semiconductor devices have been miniaturized and high-speed, copper (Cu) whose resistivity is lower than that of aluminum has been drawing attention as a wiring material for semiconductor devices. Also, forming a through electrode through a semiconductor substrate has been drawing attention since forming such a through electrode makes it possible to connect between chips with a shortest possible distance and thereby contributes to the realization of a sophisticated high-speed LSI system.

In view of the above, there have been proposed methods of forming a through electrode made of copper (which may hereinafter be simply referred to as a “Cu through electrode”) through a silicon substrate by a combination of vacuum film formation and a copper plating process (see Patent Literatures 1 to 3, for example).

FIGS. 8A to 8D schematically show a typical example of a conventional Cu through electrode forming process.

First, as shown in FIG. 8A, a non-through hole 111 (a bottomed hole) is formed in a silicon substrate 110. A barrier film 112 (e.g., a titanium film or a tantalum film) is formed on inner walls of the non-through hole 111 and a surface of the silicon substrate 110 by using a suitable vacuum film forming method (e.g., a sputtering method). The barrier film 112 is formed for the purpose of preventing silicon and copper from forming into a suicide compound. It should be noted that, usually, before the barrier film 112 is formed, an oxide film such as a SiO₂ film is formed on the inner walls of the non-through hole 111 and the surface of the silicon substrate 110 in order to insulate between the barrier film 112 and the silicon substrate 110. However, the oxide film is not shown in the drawing.

Next, as shown in FIG. 8B, a seed film 113 made of a copper material and serving as a base electrode in a copper plating process (a post-process) is formed by using a suitable vacuum film forming method (e.g., a sputtering method), such that the seed film 113 entirely covers exposed portions of the barrier film 112 in the non-through hole 111.

Thereafter, as shown in FIG. 8C, a Cu (copper) material 114 is grown in the copper plating process, and thereby the Cu material 114 is embedded in the non-through hole 111.

Then, as shown in FIG. 8D, both surfaces of the silicon substrate 110 are ground, and thereby the silicon substrate 110 including a Cu through electrode 115 is obtained.

### CITATION LIST

### Patent Literature

PTL 1: Japanese Laid-Open Patent Application Publication No. 2003-328180
PTL 2: Japanese Laid-Open Patent Application Publication No. 2007-5402
PTL 3: Japanese Laid-Open Patent Application Publication No. 2010-103406

### SUMMARY OF INVENTION

### Technical Problem

However, in the above conventional art, there are problems as described below.

Firstly, it is difficult to form a Cu through electrode in a long and narrow non-through hole whose aspect ratio exceeds a certain value (e.g., approximately 7 to 10). For example, deep inside the non-through hole, the seed film on the side wall tends to be thin and the coatability of the seed film on the sidewall is insufficient. Consequently, in the copper plating process, the Cu material does not grow properly, resulting in the formation of a void.

Secondly, the seed film around the opening of the non-through hole tends to be thicker than the seed film inside the non-through hole. Therefore, the resistivity of the seed film around the opening tends to be lower. Accordingly, since a current density when the copper plating is performed determines the plating growth rate of the Cu material, there is a case where the plating growth rate of the Cu material around the opening of the non-through hole is higher than the plating growth rate of the Cu material inside the non-through hole. In this case, in the copper plating process, the opening of the non-through hole becomes blocked by the Cu material, resulting in the formation of a void. This problem occurs particularly when the aforementioned current density is increased in order to increase the plating growth rate of the Cu material.

Thirdly, if an intended additive composition ratio in the copper plating process is lost at the time of embedding the Cu through electrode in the non-through hole, then the aforementioned void is formed.

That is, the conventional art has the following problems: uniform seed film formation over the entire non-through hole is difficult; and management of a plating bath (e.g., management of compounding of additive agents) used in the copper plating process for embedding the Cu through electrode in the non-through hole is complicated.

In view of the above, the inventors of the present invention have been developing a vacuum film forming technique capable of forming not the above non-through hole (bottomed hole) but a through-hole (bottomless hole) in a silicon substrate, and blocking an opening of the through-hole by means of a deposited film formed of copper (which may hereinafter be simply referred to as a “Cu deposited film”). The inventors of the present invention consider that the above-described problems can be overcome (details will be given below) if the Cu deposited film is made function as an electrode (seed film) in the copper plating process.

It should be noted that, in Patent Literature 2, a copper metal film is formed in a through-hole in a silicon substrate by using, for example, a sputtering method. However, since the copper metal film in Patent Literature 2 does not function as a seed film, Patent Literature 2 has no value as a reference for developing the above-described vacuum film forming technique.

The present invention has been made in view of the above. An object of the present invention is to provide a film-forming apparatus and a film-forming method capable of suitably controlling the blocked state of a through-hole opening blocked by a Cu deposited film which is used as an electrode in a copper plating process.

### Solution to Problem

In order to solve the above-described problems, one aspect of the present invention provides a film-forming apparatus including: a vacuum chamber configured to store a substrate in which a through-hole is formed and a source of copper emission; a vacuum pump configured to decompress an interior of the vacuum chamber to a predetermined degree of vacuum; a power supply configured to generate electric power applied to the substrate; and a driving mechanism for use in setting a distance between the substrate and the source of copper emission. When a copper material emitted from the source of copper emission is deposited on one main surface of the substrate to block an opening of the through-hole in the one main surface by means of a deposited film formed of the copper material, a blocked state of the opening blocked by the deposited film is adjusted based on the distance and the electric power.

The film-forming apparatus according to the above aspect of the present invention, which has the above-described configuration, is capable of suitably controlling the blocked state of the through-hole opening blocked by the Cu deposited film which is used as an electrode in a copper plating process.

In the film-forming apparatus according to another aspect of the present invention, a thickness of the deposited film blocking the opening may be reduced in accordance with an increase in the distance or an increase in the electric power. That is, in this aspect of the present invention, the idea of “thickness of the deposited film blocking the opening” has been devised, and based on the idea, suitable film-forming conditions for a film-forming process have been found out, which is a feature of this aspect of the present invention.

According to the above configuration, a warp of the substrate due to the membrane stress of the Cu deposited film can be suppressed, and also, a time required for grinding the Cu deposited film can be reduced.

In the film-forming apparatus according to yet another aspect of the present invention, a film-forming time necessary for depositing the deposited film to block the opening may be reduced in accordance with a decrease in the distance or an increase in the electric power. That is, in this aspect of the present invention, the idea of “film-forming time necessary for depositing the deposited film to block the opening” has been devised, and based on the idea, suitable film-forming conditions for a film-forming process have been found out, which is a feature of this aspect of the present invention.

According to the above configuration, the efficiency of the Cu deposited film formation can be increased.

Yet another aspect of the present invention provides a film-forming method including: a step of storing a substrate in which a through-hole is formed and a source of copper emission in a vacuum chamber; a step of decompressing an interior of the vacuum chamber to a predetermined degree of vacuum; and a blocking step of blocking an opening of the through-hole in one main surface of the substrate by means of a deposited film formed of a copper material, by depositing the copper material on the one main surface, the copper material being emitted from the source of copper emission. A blocked state of the opening blocked by the deposited film is adjusted based on a distance between the substrate and the source of copper emission and electric power applied to the substrate.

The film-forming method according to the above aspect of the present invention is capable of suitably controlling the blocked state of the through-hole opening blocked by the Cu deposited film which is used as an electrode in a copper plating process.

In the film-forming method according to yet another aspect of the present invention, a thickness of the deposited film blocking the opening may be reduced in accordance with an increase in the distance or an increase in the electric power. That is, in this aspect of the present invention, the idea of “thickness of the deposited film blocking the opening” has been devised, and based on the idea, suitable film-forming conditions for a film-forming process have been found out, which is a feature of this aspect of the present invention.

According to the above method, a warp of the substrate due to the membrane stress of the Cu deposited film can be suppressed, and also, a time required for grinding the Cu deposited film can be reduced.

In the film-forming method according to yet another aspect of the present invention, a film-forming time necessary for depositing the deposited film to block the opening may be reduced in accordance with a decrease in the distance or an increase in the electric power. That is, in this aspect of the present invention, the idea of “film-forming time necessary for depositing the deposited film to block the opening” has been devised, and based on the idea, suitable film-forming conditions for a film-forming process have been found out, which is a feature of this aspect of the present invention.

According to the above method, the efficiency of the Cu deposited film formation can be increased.

The film-forming method according to yet another aspect of the present invention may further include a copper plating step of forming a through electrode in the through-hole by applying a current to a seed film after the blocking step, the seed film being the deposited film deposited on the one main surface.

In the film-forming method according to yet another aspect of the present invention, in the copper plating step, the through electrode may be formed in such a manner as to cause copper to grow from the seed film toward another main surface of the substrate.

According to the above method, a substrate including a Cu through electrode can be obtained through the copper plating step.

The above object, other objects, features, and advantages of the present invention will be made clear by the following detailed description of a preferred embodiment with reference to the accompanying drawings.

### Advantageous Effects of Invention

The present invention makes it possible to obtain a film-forming apparatus and a film-forming method capable of suitably controlling the blocked state of a through-hole opening blocked by a Cu deposited film which is used as an electrode in a copper plating process.

### BRIEF DESCRIPTION OF DRAWINGS

FIGS. 1A to 1C show an example of a Cu through electrode forming process according to one embodiment of the present invention.

FIG. 2 shows an example of the configuration of a sputtering apparatus according to the embodiment of the present invention.

FIG. 3 is a diagram used to describe a blocked state of a through-hole opening in a silicon substrate, the through-hole opening being blocked by a Cu deposited film.

FIG. 4 shows a relationship between film-forming conditions and characteristics of the Cu deposited film according to the sputtering apparatus of the present embodiment.

FIG. 5 shows a relationship between film-forming conditions and characteristics of the Cu deposited film according to the sputtering apparatus of the present embodiment.

FIG. 6 shows a relationship between film-forming conditions and characteristics of the Cu deposited film according to the sputtering apparatus of the present embodiment.

FIG. 7 is a sectional photograph showing a state where Cu through electrodes are formed in respective through-holes in a silicon substrate.

FIGS. 8A to 8D show a typical example of a conventional Cu through electrode forming process.

### DESCRIPTION OF EMBODIMENTS

Hereinafter, specific examples of a film-forming apparatus and a film-forming method according to one embodiment of the present invention are described with reference to the drawings. In the drawings, the same or corresponding elements are denoted by the same reference signs, and repeating the same descriptions of such elements is avoided below as necessary.

The specific description given below merely gives examples of the above-described features of the film-forming apparatus and the film-forming method. For example, in the description of specific examples below, the same terms as or corresponding terms to those used above to specify respective components of the film-forming apparatus may be denoted by reference signs as necessary. In such a case, in the description below, each component specified by a term denoted by a reference sign is merely an example of a component that is specified by the same term in the above description of the film-forming apparatus.

Therefore, the above-described features of the film-forming apparatus and the film-forming method are not limited by the specific description given below.

### Embodiment

### <Brief Description of Film-Forming Technique of Present Embodiment>

First, formation of a Cu through electrode according to the embodiment of the present invention is briefly described with reference to the drawings.

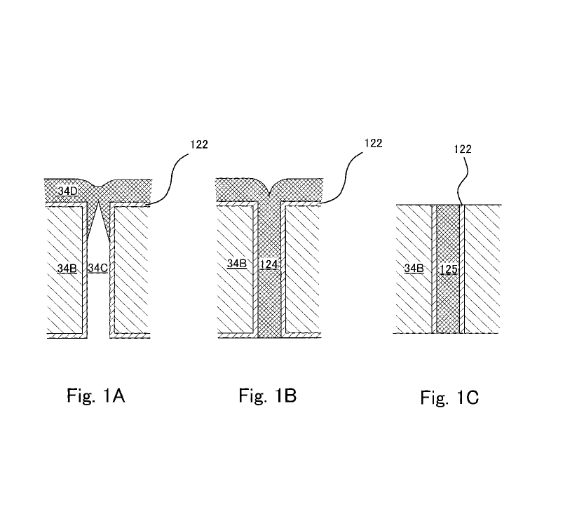

FIGS. 1A to 1C show one example of a Cu through electrode forming process according to the embodiment of the present invention.

First, a plurality of through-holes 34C are formed in a silicon substrate 34B in a manner as shown in FIG. 1A. A barrier film 122 (e.g., a titanium film or a tantalum film) is formed on the inner wall of each through-hole 34C and main surfaces of the silicon substrate 34B by using a suitable vacuum film forming method (e.g., a sputtering method).

Next, as shown in FIG. 1A, a deposited film 34D formed of a copper material (Cu deposited film 34D) is deposited on one main surface of the silicon substrate 34B, such that the opening of the through-hole 34C in the one main surface is blocked by the Cu deposited film 34D. It should be noted that the Cu deposited film 34D serves as an electrode (seed film) in a copper plating process. As will hereinafter be described in detail, the Cu deposited film 34D is formed by using a sputtering method.

Thereafter, in the copper plating process, a Cu (copper) material 124 is grown from the Cu deposited film 34D at the opening of the through-hole 34C toward the other main surface of the silicon substrate 34B, and thereby the Cu material 124 is embedded in the through-hole 34C as shown in FIG. 1B.

Finally, as shown in FIG. 1C, both surfaces of the silicon substrate 34B are ground, and thereby the silicon substrate 34B including a Cu through electrode 125 is obtained.

The above technique of forming the Cu through electrode 125 in the through-hole 34C by copper plating using the Cu deposited film 34D as an electrode in the copper plating process (hereinafter, simply referred to as a “present film-forming technique”) is considered to be superior to the conventional art from the standpoint of reducing the formation of a void in the through-hole 34C when forming the Cu through electrode 125. Specifically, from the Cu deposited film 34D blocking the opening of the through-hole 34C, the Cu material 124 grows in the extending direction of the long and narrow through-hole 34C. This makes it possible to suppress the formation of a void due to the growth of the Cu material 124. It should be noted that such a void formation suppressing effect has been confirmed from experimental results regarding the copper plating process, which will be described below.

Moreover, the present film-forming technique is considered to be superior to the conventional art also in the following points: the present film-forming technique does not require uniform formation of a seed film around the opening of the through-hole 34C and the side wall deep inside the through-hole 34C, and allows the management of a plating bath used in the copper plating process to be simplified.

Furthermore, since the present film-forming technique is capable of suitably and sufficiently increasing the current density that determines the plating growth rate of the Cu material (i.e., since a problem of void formation due to blockage of the opening does not occur unlike the conventional art), the present film-forming technique is considered to be superior to the conventional art in terms of improvement in the plating growth efficiency of the Cu through electrode 125.

### <Configuration of Film-Forming Apparatus of Present Embodiment>

Next, the configuration of a sputtering apparatus 100, which is one example of the film-forming apparatus according to the present embodiment, is described in detail with reference to the drawings.

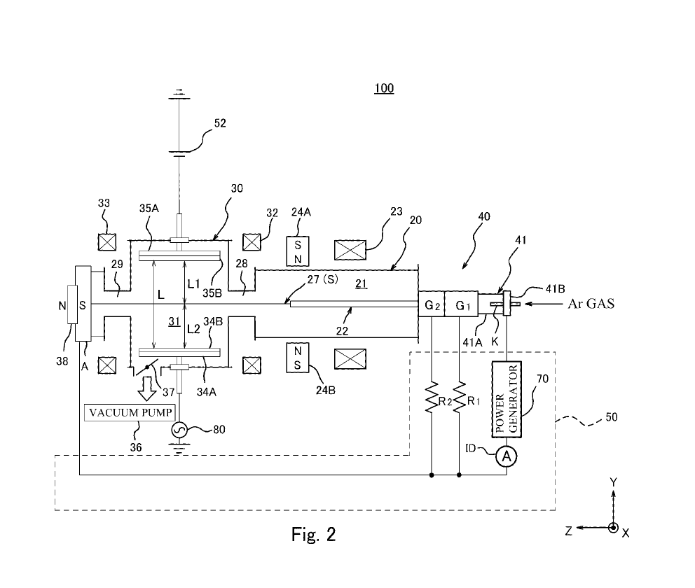

FIG. 2 shows an example of the configuration of the sputtering apparatus according to the embodiment of the present invention.

It should be noted that, for the sake of convenience of the description herein, the configuration of the sputtering apparatus 100 is described on the basis that, as shown in FIG. 2, the direction of plasma transport is a Z-direction; a direction that is orthogonal to the Z-direction and that is the magnetization direction of bar magnets 24A and 24B (described below) is a Y-direction; and a direction orthogonal to both of the Z-direction and the Y-direction is an X-direction.

As shown in FIG. 2, the sputtering apparatus 100 according to the present embodiment is substantially cross-shaped on a YZ plane. The sputtering apparatus 100 includes: a plasma gun 40 configured to generate discharge plasma with a high density; a cylindrical non-magnetic (e.g., stainless steel or glass) sheet plasma converting chamber 20 whose center coincides with an axis extending in the Z-direction; and a cylindrical non-magnetic (e.g., stainless steel) vacuum film forming chamber 30 whose center coincides with an axis extending in the Y-direction. These components 40, 20, and 30 are arranged in said order when viewed in the discharge plasma transport direction (Z-direction). As shown in FIG. 2, the sputtering apparatus 100 further includes a plasma gun power supply 50 configured to supply the plasma gun 40 with electric power for use in generating discharge.

It should be noted that the above-described components 40, 20 and 30 are hermetically in communication with one another via passages through which discharge plasma is transported.

First, configurations of the plasma gun 40 and the plasma gun power supply 50 of the sputtering apparatus 100 are described.

As shown in FIG. 2, the plasma gun 40 of the sputtering apparatus 100 includes a cathode unit 41 and a pair of intermediate electrodes G₁ and G₂.

The cathode unit 41 includes a cylindrical glass tube 41A formed of heat-resistant glass and a discoid cover member 41B. The interior of the cathode unit 41 serves as discharge space. The glass tube 41A is hermetically provided between the intermediate electrode G₁ and the cover member 41B by suitable fasteners (such as bolts; not shown). Accordingly, plasma generated in the discharge space can be drawn from the cathode unit 41 to the outside via a through-hole (not shown) of the intermediate electrode G₁.

A cathode K formed of lanthanum hexaboride (LaB₆) capable of emitting thermoelectrons for plasma discharge induction is disposed at the cover member 41B. Also, the cover member 41B is provided with a discharge gas supply unit (not shown) configured to guide an argon (Ar) gas to the discharge space. The argon (Ar) gas serves as a discharge gas to be ionized by the discharge.

As shown in FIG. 2, the plasma gun power supply 50 of the sputtering apparatus 100 includes: a power generator 70 configured to supply electric power to the plasma gun 40; and resistor elements R₁ and R₂ provided corresponding to the intermediate electrodes G₁ and G₂, respectively, and configured to limit a current flowing through the intermediate electrodes G₁ and G₂.

The intermediate electrode G₁ is connected to the power generator 70 via the resistor element R₁ such that, in the discharge space of the plasma gun 40, auxiliary discharge (glow discharge) between the intermediate electrode G₁ and the cathode K can be suitably maintained. Similarly, the intermediate electrode G₂ is connected to the power generator 70 via the resistor element R₂ such that, in the discharge space of the plasma gun 40, auxiliary discharge (glow discharge) between the intermediate electrode G₂ and the cathode K can be suitably maintained.

In the glow discharge, charged particles (here, Ar⁺ and electrons) are supplied to the discharge space of the plasma gun 40 through secondary electron emission occurring when Ar⁺ collides with the cathode K and through argon ionization by electrons. As a result, discharge plasma that is a mass of the charged particles is generated in the discharge space of the plasma gun 40. Then, the plasma gun 40 shifts to main discharge (arc discharge), which is based on thermoelectron emission occurring when the cathode K is heated. Thus, the plasma gun 40 is a plasma gun of a pressure gradient type, which realizes high-density discharge between the cathode K and an anode A by low-voltage large-current arc discharge based on the plasma gun power supply 50.

In the power generator 70, a switch can be made between a state where the cathode K and a transformer are connected and a state where the cathode K and a constant-current power supply are connected, by using a power supply changeover switch although the details of such a configuration are not shown in the drawing.

The former state is selected when glow discharge is performed by the plasma gun 40. In this case, a primary voltage of 200 V at a commercial frequency is applied between primary-side terminals of the transformer. This induces a predetermined secondary voltage between secondary-side terminals of the transformer. After the secondary voltage is rectified by a rectifier circuit, the rectified voltage is applied to the plasma gun 40.

On the other hand, the latter state is selected when arc discharge is performed by the plasma gun 40. As a result, the plasma gun 40 is subjected to constant-current control by the plasma gun power supply 50 (constant-current power supply), and thereby a discharge current ID flowing from the anode A to the cathode K becomes constant. It should be noted that the discharge current ID is adjustable by using the plasma gun power supply 50.

In the above manner, columnar arc discharge plasma (hereinafter, referred to as “columnar plasma 22”) distributed at a substantially uniform density with respect to a transport center in the Z-direction is drawn to the sheet plasma converting chamber 20 through a passage (not shown) extending between a second end of the plasma gun 40 in the Z-direction and a first end of the sheet plasma converting chamber 20 in the Z-direction.

Next, the configuration of the sheet plasma converting chamber 20 of the sputtering apparatus 100 and components around the sheet plasma converting chamber 20 are described.

The sheet plasma converting chamber 20 includes columnar transport space 21, whose center coincides with the axis extending in the Z-direction and whose pressure can be reduced.

A circular first magnet coil 23 (air-core coil) is disposed around the side surface of the sheet plasma converting chamber 20. The first magnet coil 23 surrounds the sheet plasma converting chamber 20 and exerts force that causes the columnar plasma 22 to move in the Z-direction. It should be noted that a current flowing in such a direction as to cause the cathode K side to serve as the south pole and cause the anode A side to serve as the north pole is supplied to the winding wire of the first magnet coil 23.

Moreover, a pair of square bar magnets 24A and 24B (permanent magnets; a pair of magnetic field generators) extending in the X-direction are arranged at the front side of the first magnet coil 23 in the Z-direction (i.e., the side closer to the anode A) so as to sandwich the sheet plasma converting chamber 20 (transport space 21), such that the bar magnets 24A and 24B are spaced apart from each other in the Y-direction by a predetermined distance, and such that the north poles of the respective bar magnets 24A and 24B face each other.

Owing to an interaction between a coil magnetic field generated in the transport space 21 by the first magnet coil 23 and a magnetic field generated in the transport space 21 by the bar magnets 24A and 24B, the columnar plasma 22 is converted into uniform sheet-shaped plasma (hereinafter referred to as “sheet plasma 27”) that spreads along an XZ plane (hereinafter referred to as a “main surface S”) including the transport center in the transport direction (Z-direction).

Accordingly, the sheet plasma 27 is drawn into the vacuum film forming chamber 30 through a slit-like bottle neck portion 28 shown in FIG. 2, which allows the sheet plasma 27 to pass through. The bottle neck portion 28 is disposed between a second end of the sheet plasma converting chamber 20 in the Z-direction and the side wall of the vacuum film forming chamber 30.

It should be noted that the space (the dimension in the Y-direction), the thickness (the dimension in the Z-direction), and the width (the dimension in the X-direction) of the bottle neck portion 28 are designed such that the bottle neck portion 28 allows the sheet plasma 27 to suitably pass through.

Next, the configuration of the vacuum film forming chamber 30 of the sputtering apparatus 100 is described.

The vacuum film forming chamber 30 is, for example, a vacuum chamber for use in a sputtering process, which is configured to dislodge the material of a target 35B as sputtered particles by utilizing collision energy of Ar⁺ in the sheet plasma 27.

The vacuum film forming chamber 30 includes columnar film-forming space 31, whose center coincides with the axis extending in the Y-direction and whose pressure can be reduced. The film forming space 31 is vacuumed by using a vacuum pump 36 (e.g., a turbopump) through an exhaust port that is openable and closable by a valve 37. In this manner, the pressure of the film forming space 31 is quickly reduced to such a degree of vacuum that the sputtering process can be performed.

In the vertical direction (Y-direction), the film forming space 31 is functionally divided, with reference to its central space that corresponds to the space of the bottle neck portion 28 and that extends along the horizontal plane (XZ plane), into target space storing the target 35B which is a plate-shaped target and substrate space storing the substrate 34B which is a plate-shaped substrate.

Specifically, the target 35B is stored in the target space which is positioned above the central space in a state where the target 35B is attached to a target holder 35A. The target 35B is configured to be movable vertically (Y-direction) in the target space by a suitable actuator (a driving mechanism which is not shown). Accordingly, a distance L1 between the target 35B and the sheet plasma 27 can be adjusted to a desired distance.

Meanwhile, the substrate 34B is stored in the substrate space which is positioned below the central space in a state where the substrate 34B is attached to a substrate holder 34A (e.g., an electrostatic chuck). The substrate 34B is configured to be movable vertically (Y-direction) in the substrate space by a suitable actuator (a driving mechanism which is not shown). Accordingly, a distance L2 between the substrate 34B and the sheet plasma 27 can be adjusted to a desired distance.

It should be note that the central space is the space that allows major components of the sheet plasma 27 to be transported therein in the vacuum film forming chamber 30.

In the above manner, the target 35B and the substrate 34B are arranged so as to be spaced apart from each other in the thickness direction of the sheet plasma 27 (Y-direction) by a certain suitable distance L (hereinafter, simply referred to as a “T/S distance L”) such that, in the film-forming space 31, the target 35B and the substrate 34B are in contraposition to each other with the sheet plasma 27 placed in between.

As described above with reference to FIG. 1, the present embodiment intends to obtain a silicon substrate including a Cu through electrode for use in a semiconductor device. Therefore, in the present embodiment, after the Cu target 35B which serves as a source of copper emission and the silicon substrate 34B in which a large number of through-holes are formed are stored in the vacuum film forming chamber 30, the vacuum film forming chamber 30 is decompressed. Then, the sheet plasma 27 is transported into the vacuum film-forming apparatus 30, in which the degree of vacuum is maintained at approximately 1.0 Pa to 2.0 Pa. Thereafter, a deposited film (Cu deposited film) formed of the copper (Cu) material of the Cu target 35B, the copper (Cu) material having been sputtered by Ar⁺ in the sheet plasma 27, is formed on one main surface of the silicon substrate 34B.

Here, the present embodiment has a feature of blocking through-hole openings in the one main surface of the silicon substrate 34B by means of the Cu deposited film under suitable film-forming conditions. The details of the feature will be described below.

As shown in FIG. 2, in the sputtering process, a constant bias voltage (negative voltage) is applied to the Cu target 35B by a DC bias supply 52. In this example, −1000V is applied as the bias voltage to the Cu target 35B. This causes Ar⁺ in the sheet plasma 27 to be attracted toward the target 35B. Then, collision energy between Ar⁺ and the Cu target 35B causes Cu particles to be emitted from the Cu target 35B such that the Cu particles are dislodged from the Cu target 35B toward the silicon substrate 34B. As a result, the aforementioned Cu deposited film is formed on the silicon substrate 34B.

Moreover, as shown in FIG. 2, in the sputtering process, a predetermined magnitude of RF power is applied to the substrate holder 34A (silicon substrate 34B) by an RF power supply 80. In this example, the RF power is biased to a negative voltage. The magnitude of the RF power is adjustable by using the RF power supply 80. Accordingly, when part of the Cu particles emitted from the Cu target 35B passes through the sheet plasma 27, the Cu particles are ionized due to the energy of the sheet plasma 27 so as to be positively charged. Therefore, it is considered that, based on the magnitude of the RF power, entry of such Cu⁺ particles into the through-hole openings of the silicon substrate 34B can be adjusted to be in a desired direction.

Next, a description is given of components around the vacuum film forming chamber 30 that are in a position opposed to the bottle neck portion 28 in the Z-direction.

In the position, the anode A is disposed near the side wall of the vacuum film forming chamber 30. A passage 29 through which the plasma passes is provided between the side wall and the anode A.

A reference potential is applied between the anode A and the cathode K. The anode A serves to collect charged particles (electrons in particular) in the sheet plasma 27 that are formed by the arc discharge between the cathode K and the anode A.

A permanent magnet 38 is disposed on the rear surface of the anode A (the rear surface is opposite to the surface facing the cathode K), such that the south pole of the permanent magnet 38 is on the anode A side, and the north pole of the permanent magnet 38 is on the atmosphere side. Therefore, a line of magnetic force along the XZ plane, the line of magnetic force being emitted from the north pole of the permanent magnet 38 and entering the south pole of the permanent magnet 38, causes the sheet plasma 27 to narrow down in the width direction (X-direction), such that the sheet plasma 27 moving toward the anode A is suppressed from spreading in the width direction. Thus, the charged particles of the sheet plasma 27 are suitably collected by the anode A.

Circular second and third magnet coils 32 and 33 (air-core coils), forming a pair of magnet coils, sandwich the film forming space 31 in a manner to face the side wall of the vacuum film forming chamber 30, and are disposed such that their different poles face each other (in this example, the north pole of the second magnet coil 32 and the south pole of the third magnet coil 33 face each other).

The second magnet coil 32 is disposed at a suitable position in the Z-direction between the vacuum film forming chamber 30 and the bar magnets 24A and 24B. The third magnet coil 33 is disposed at a suitable position in the Z-direction between the side wall of the vacuum film forming chamber 30 and the anode A.

Owing to a coil magnetic field generated by the pair of second and third magnet coils 32 and 33 (e.g., approximately 10 G to 300 G), the sheet plasma 27 is shaped such that the sheet plasma 27 is suitably suppressed from spreading in the width direction (X-direction).

As described above, the sputtering apparatus 100 according to the present embodiment has a feature of being able to separately adjust each of the various film-forming conditions for the sputtering process. For instance, in this example, each of the following conditions can be adjusted separately: the discharge current ID of the sheet plasma 27; the bias voltage applied to the Cu target 35B; the RF power applied to the silicon substrate 34B; and the T/S distance L. In view of this, studies have been conducted, as described below, on film-forming conditions that allow the features of the sputtering apparatus 100 to be made use of and that allow the Cu deposited film to be suitably formed on the silicon substrate 34B by means of the sputtering apparatus 100.

### <Study Experiments on Cu Deposited Film Formation>

It has been found out from study experiments below that the blocking, by the Cu deposited film, of a through-hole opening in a main surface of the silicon substrate 34B can be suitably controlled based on the RF power applied to the silicon substrate 34B and the T/S distance L.

It should be noted that the study experiments were conducted under the following fixed conditions: the discharge current ID of the sheet plasma 27 was 100 A; the bias voltage applied to the Cu target 35B was −1000V; and the degree of vacuum during the sputtering process was 1.6 Pa.

The influences of the RF power and the T/S distance L on the Cu deposited film vary in accordance with the size of the silicon substrate 34B and the Cu target 35B. Therefore, the silicon substrate 34B having a standard diameter of 300 mm and the Cu target 35B having a standard diameter of 450 mm are used in the study experiments. Moreover, in the study experiments, when the T/S distance L is to be changed, the distance L1 between the target 35B and the sheet plasma 27 is fixed to 40 mm, and only the distance L2 between the silicon substrate 34B and the sheet plasma 27 is changed. Specifically, L1=40 mm and L2=60 mm in the case of L=100 mm; L1=40 mm and L2=160 mm in the case of L=200 mm; and L1=40 mm and L2=260 mm in the case of L=300 mm.

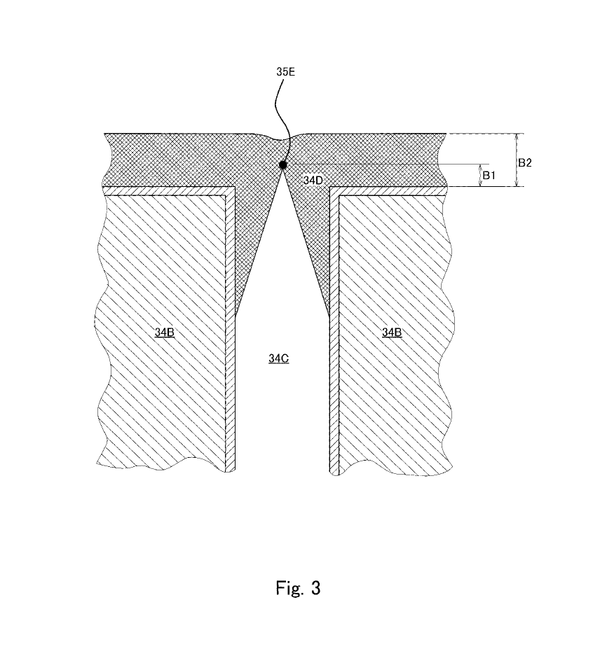

As shown in FIG. 3, in the study experiments, a position where the Cu deposited film 34D deposited on the silicon substrate 34B blocks the opening of the through-hole 34C in one main surface of the silicon substrate 34B is a blocking point 35E; the thickness of the Cu deposited film 34D up to the blocking point 35E (i.e., the thickness of the Cu deposited film 34D blocking the opening of the through-hole 34C) is a blocking film thickness B1; and the thickness of the Cu deposited film 34D up to its surface is a surface thickness B2. Thus, in the present embodiment, the idea of “blocking point 35E” and the idea of “blocking film thickness B1” have been devised, and based on these ideas, suitable film-forming conditions for the sputtering process have been found out, which is a feature of the present embodiment.

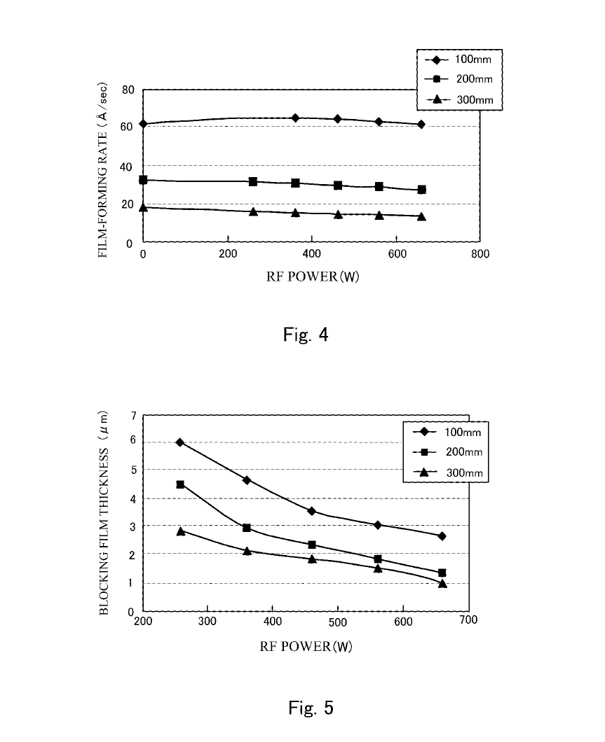

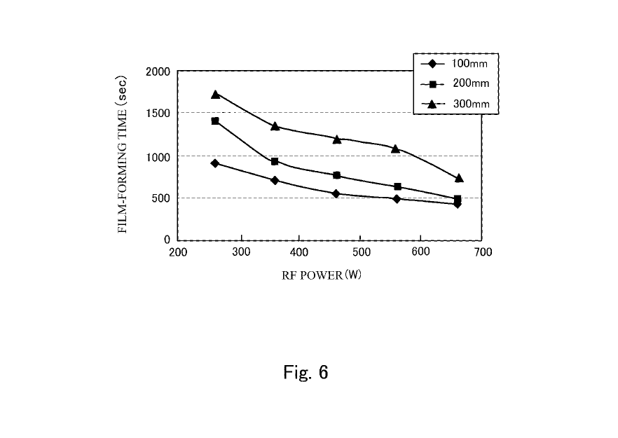

FIG. 4, FIG. 5, and FIG. 6 show relationships between film-forming conditions and characteristics of the Cu deposited film according to the sputtering apparatus of the present embodiment.

In FIG. 4, the horizontal axis represents the RF power (W) applied to the silicon substrate 34B, and the vertical axis represents the film-forming rate (A/sec) of the Cu deposited film. FIG. 4 shows a profile indicating a relationship between the RF power (W) applied to the silicon substrate 34B and the film-forming rate (A/sec) of the Cu deposited film while using the T/S distance L as a parameter. It should be noted that a value that is estimated from the surface thickness B2 in FIG. 3 at a point when a predetermined film-forming time has elapsed is used as the film-forming rate of the Cu deposited film in FIG. 4.

It is understood from FIG. 4 that the film-forming rate of the Cu deposited film increases in accordance with a decrease in the T/S distance L when the T/S distance L is reduced from 300 mm to 200 mm and then to 100 mm.

Meanwhile, there is a tendency for the film-forming rate of the Cu deposited film to slightly decrease when the RF power increases beyond 400 W. It is considered that this phenomenon is caused when etching occurs on the Cu deposited film due to the energy of Cu⁺ and Ar⁺.

In FIG. 5, the horizontal axis represents the RF power (W) applied to the silicon substrate 34B, and the vertical axis represents the blocking film thickness B1 (μm). FIG. 5 shows a profile indicating a relationship between the RF power (W) applied to the silicon substrate 34B and the blocking film thickness B1 (μm) while using the T/S distance L as a parameter.

It is understood from FIG. 5 that the blocking film thickness B1 can be reduced by increasing the T/S distance L from 100 mm to 200 mm and then to 300 mm. It is also understood from FIG. 5 that the blocking film thickness B1 can be reduced by increasing the RF power when the RF power is in the range of approximately 200 W to approximately 700 W. By reducing the Cu deposited film 34D in such a manner, a warp of the silicon substrate 34B due to the membrane stress of the Cu deposited film can be reduced, and also, a time required for grinding the Cu deposited film can be reduced.

It should be noted that FIG. 5 shows the blocking film thickness B1 when the diameter of the opening of the through-hole 34C is approximately 2.0 μm. However, even if the diameter of the opening of the through-hole 34C varies, the study results (i.e., the tendency indicated by the profile in FIG. 5) are regarded as universally applicable regardless of an increase or decrease in the diameter of the opening of the through-hole 34C since it is considered that the proportion of the blocking film thickness B1 to the diameter of the opening of the through-hole 34C is fixed.

To be specific, under the condition that the T/S distance L is 100 mm and the RF power is 660 W, the blocking film thickness B1 is approximately 2.6 μm when the diameter of the opening of the through-hole 34C is approximately 2.0 μm, and the blocking film thickness B1 is approximately 6.1 μm when the diameter of the opening of the through-hole 34C is approximately 5.0 μm.

The proportion of the blocking film thickness B1 to the diameter of the opening of the through-hole 34C when the diameter of the opening of the through-hole 34C is approximately 2.0 μm (2.6 μm/2.0 μm=1.3) is substantially equal to the proportion of the blocking film thickness B1 to the diameter of the opening of the through-hole 34C when the diameter of the opening of the through-hole 34C is approximately 5.0 μm (6.1 μm/5.0 μm=1.2). Therefore, even if the diameter of the opening of the through-hole 34C is varied, it is considered that the blocking film thickness B1 indicated by the vertical axis of FIG. 5 is merely shifted in accordance with the above proportion over the entire range of the RF power indicated by the horizontal axis of FIG. 5. That is, whether the diameter of the opening of the through-hole 34C is approximately 2.0 μm or approximately 5.0 μm, it is considered that the profile of FIG. 5 indicates substantially the same tendency.

In FIG. 6, the horizontal axis represents the RF power (W) applied to the silicon substrate 34B, and the vertical axis represents the film-forming time (sec) of the Cu deposited film. FIG. 6 shows a profile indicating a relationship between the RF power (W) applied to the silicon substrate 34B and the film-forming time (sec) of the Cu deposited film while using the T/S distance L as a parameter. It should be noted that a value obtained by dividing the blocking film thickness B1 of FIG. 5 by the film-forming rate of FIG. 4 is used as the film-forming time of the Cu deposited film in FIG. 6. That is, the film-forming time corresponds to a time necessary for depositing the Cu deposited film 34D for blocking the opening of the through-hole 34C.

It is understood from FIG. 6 that the film-forming time of the Cu deposited film 34D can be reduced by reducing the T/S distance L from 300 mm to 200 mm and then to 100 mm. It is also understood from FIG. 6 that the film-forming time of the Cu deposited film 34D can be reduced by increasing the RF power when the RF power is in the range of approximately 200 W to approximately 700 W.

As readily understood from the above description, the sputtering apparatus 100 and the sputtering method according to the present embodiment provide an advantageous effect of being able to select optimal film-forming conditions regarding the blocking film thickness B1 of the Cu deposited film 34D and the film-forming time of the Cu deposited film 34D in accordance with preceding and subsequent processes to perform.

### <Study Experiment on Suitability of Cu Through Electrode Formation in Copper Plating Process>

By using the above-described sputtering apparatus 100, a Cu deposited film was deposited on one main surface of a silicon substrate, and through-hole openings in the one main surface were blocked by the Cu deposited film. Then, the Cu deposited film on the silicon substrate was used as an electrode (seed film) in a copper plating process, in which a current was applied to the seed film and thereby copper plating for forming a Cu through electrode in each through-hole in the silicon substrate was performed.

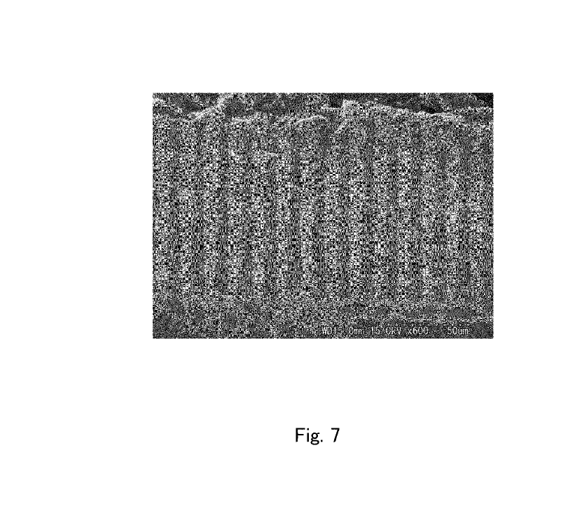

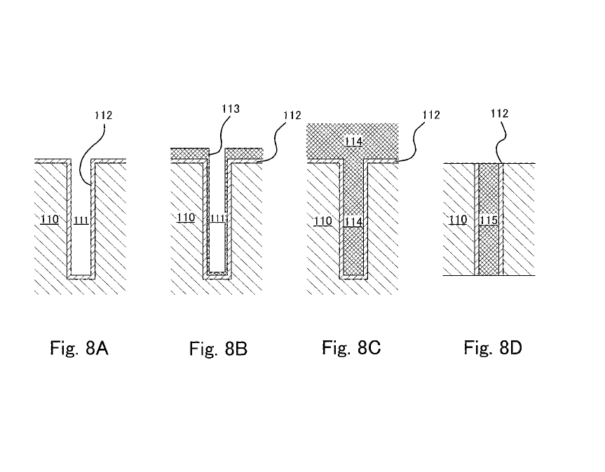

As a result, as shown in FIG. 7, it was confirmed that it was possible to embed, in each through-hole, the Cu through electrode with no void formed therein. It should be noted that the copper plating was performed under usual conditions for a copper sulfate plating process (e.g., copper sulfate pentahydrate: 200 g/L, sulfuric acid: 70 g/L), and the current density was set to 10 mA/cm².

### <Variation>

The above description has been given while taking the sputtering apparatus 100 as one example of the film-forming apparatus according to the present embodiment. However, the range of application of the present film-forming technique is not limited to sputtering technology. The present film-forming technique is considered to be applicable to other film-forming methods such as a vacuum deposition method, so long as the methods are vacuum film forming methods using PVD (Physical Vapor Deposition). Thus, the present embodiment makes it possible to obtain a silicon substrate including a Cu through electrode, by using a PVD method which is less expensive than CVD (Chemical Vapor Deposition) methods.

From the foregoing description, numerous modifications and other embodiments of the present invention are obvious to one skilled in the art. Therefore, the foregoing description should be interpreted only as an example and is provided for the purpose of teaching the best mode for carrying out the present invention to one skilled in the art. The structural and/or functional details may be substantially altered without departing from the spirit of the present invention.

### INDUSTRIAL APPLICABILITY

The present invention makes it possible to obtain a film-forming apparatus and a film-forming method capable of suitably controlling the blocked state of a through-hole opening blocked by a Cu deposited film which is used as an electrode in a copper plating process. Therefore, the present invention is applicable to, for example, a PVD apparatus for use in a sputtering method or the like for forming an electrode to be used in a copper plating process.

### REFERENCE SIGNS LIST

20 sheet plasma converting chamber
21 transport space
22 columnar plasma
23 first magnet coil
24A, 24B bar magnet
36 vacuum pump
37 valve
27 sheet plasma
28 bottle neck portion
29 passage
30 vacuum film forming chamber
31 film-forming space
32 second magnet coil
33 third magnet coil
34A substrate holder
34B substrate (silicon substrate)
35A target holder
35B target (Cu target)
38 permanent magnet
40 plasma gun
41 cathode unit
41A glass tube
41B cover member
50 plasma gun power supply
52 bias supply
70 power generator
80 RF power supply
100 sputtering apparatus
A anode
G₁, G₂ intermediate electrode
K cathode
R₁, R₂ resistor element
S main surface

1. A film-forming apparatus comprising:
a vacuum chamber configured to store a substrate in which a through-hole is formed and a source of copper emission;
a vacuum pump configured to decompress an interior of the vacuum chamber to a predetermined degree of vacuum;
a power supply configured to generate electric power applied to the substrate; and
a driving mechanism for use in setting a distance between the substrate and the source of copper emission, wherein
when a copper material emitted from the source of copper emission is deposited on one main surface of the substrate to block an opening of the through-hole in the one main surface by means of a deposited film formed of the copper material, a blocked state of the opening blocked by the deposited film is adjusted based on the distance and the electric power.

2. The film-forming apparatus according to claim 1, wherein a thickness of the deposited film blocking the opening is reduced in accordance with an increase in the distance or an increase in the electric power.

3. The film-forming apparatus according to claim 1, wherein a film-forming time necessary for depositing the deposited film to block the opening is reduced in accordance with a decrease in the distance or an increase in the electric power.

4. A film-forming method comprising:
a step of storing a substrate in which a through-hole is formed and a source of copper emission in a vacuum chamber;
a step of decompressing an interior of the vacuum chamber to a predetermined degree of vacuum; and
a blocking step of blocking an opening of the through-hole in one main surface of the substrate by means of a deposited film formed of a copper material, by depositing the copper material on the one main surface, the copper material being emitted from the source of copper emission, wherein
a blocked state of the opening blocked by the deposited film is adjusted based on a distance between the substrate and the source of copper emission and electric power applied to the substrate.

5. The film-forming method according to claim 4, wherein a thickness of the deposited film blocking the opening is reduced in accordance with an increase in the distance or an increase in the electric power.

6. The film-forming method according to claim 4, wherein a film-forming time necessary for depositing the deposited film to block the opening is reduced in accordance with a decrease in the distance or an increase in the electric power.

7. The film-forming method according to claim 4, further comprising a copper plating step of forming a through electrode in the through-hole by applying a current to a seed film after the blocking step, the seed film being the deposited film deposited on the one main surface.

8. The film-forming method according to claim 7, wherein
in the copper plating step, the through electrode is formed in such a manner as to cause copper to grow from the seed film toward another main surface of the substrate.
